(19) United States
(12) Patent Application Publication
(10) Pub. No.: US 2026/0052938 A1
(43) Pub. Date: Feb. 19, 2026

(54) NOVEL MONITOR FUNCTION WITH ROBOT ARM AND FOUP

(71) Applicant: Taiwan Semiconductor Manufacturing Co., Ltd., Hsinchu (TW)

(72) Inventors: Chung Hsien LIAO, Hsinchu (TW); Jui-Mu CHO, Hsinchu (TW); Bang-Yu HUANG, Hsinchu (TW); Chien-Fang LIN, Hsinchu (TW); Chia-Yu TANG, Hsinchu (TW); Chih-Kuo CHANG, Hsinchu (TW)

(21) Appl. No.: 18/807,102

(22) Filed: Aug. 16, 2024

(51) Int. Cl. H01L 21/67; B25J 11/00; G05B 19/418; H01L 21/677; H01L 21/687

(52) U.S. Cl. CPC H01L 21/67265; G05B 19/41835; H01L 21/67766; H01L 21/67772; H01L 21/67778; H01L 21/68707; B25J 11/0095; G05B 2219/31001

(57) ABSTRACT

A transport case is configured to hold a plurality of wafers for transport of the wafers. The transport case includes a sensor system configured to generate sensor data indicative of conditions within the transport case while the transport case is docked at a load/unload system of a semiconductor process tool. The transport case includes a communication system configured to transmit the sensor data from the sensor system to an external control system.

### BACKGROUND

Fabrication of integrated circuits is typically accomplished by performing a large number of processing steps on semiconductor wafers. The processing steps typically result in the formation of a large number of transistors in highly complex arrangements in conjunction with a semiconductor substrate. The processing steps also result in the formation of dielectric layers, metal interconnects, plugs, and other integrated circuit structures and components.

Processing steps may be performed using various tools at a semiconductor fabrication facility. Such tools can include thin-film deposition tools, etching tools, ion implantation tools, annealing tools, planarization tools, cleaning tools, dicing tools, and various other tools. After a process has been performed on a wafer with a particular tool, the wafer may be stored at a storage location or transferred to the location of another tool for a next processing step. The tools and storage facilities may be at various locations within a same fabrication facility, within a same building at the fabrication facility, within different buildings at the fabrication facility, or at a separate fabrication facility.

The wafers may be loaded into a transport case for storage during transfers or for storage between transfers. However, storage and transport of wafer introduces various risks of damage to the wafers. If wafers are damaged, then the integrated circuits that will be diced from the wafers may function poorly or may not function at all. Wafer yields may be reduced and electronic devices that will utilize the integrated circuits may not work properly.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventors' approach to the particular problem, which, in and of itself, may also be inventive.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor processing system, in accordance with some embodiments.

FIG. 2 is an illustration of a wafer transport case, in accordance with some embodiments.

FIGS. 3A and 3B are illustrations of a transport case at an unload/load port, in accordance with some embodiments.

FIGS. 4 and 5 are illustrations of a wafer transport case and a load/unload station, in accordance with some embodiments.

FIG. 6A is a side view of a portion of a wafer transport case, in accordance with some embodiments.

FIG. 6B is a top view of a portion of a wafer transport case, in accordance with some embodiments.

FIG. 6C is a top view of a portion of a wafer transport case, in accordance with some embodiments.

FIGS. 7A, 7B, 8, 9A, and 9B are illustrations of a wafer transport case and a load/unload station, in accordance with some embodiments.

FIG. 10 is an illustration of a wafer transport case, in accordance with some embodiments.

FIG. 11 is a block diagram of a semiconductor processing system, in accordance with some embodiments.

FIG. 12 is a flow diagram of a method for operating a semiconductor processing system, in accordance with some embodiments.

FIG. 13 is a flow diagram of a method for operating a semiconductor processing system, in accordance with some embodiments.

FIG. 14 is a graph of sensor data of a transport case, in accordance with some embodiments.

FIG. 15 is a flow diagram of a method for operating a semiconductor processing system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure help ensure that semiconductor wafers or other sensitive semiconductor processing equipment or materials are not damaged during transport, loading, and unloading. Embodiments of the present disclosure provide a wafer transport case, often termed a front opening unified pod (FOUP), with a sensor system including a plurality of sensors mounted within the transport case. The transport case includes a plurality of slots each configured to receive and hold a wafer. The sensor system generates sensor data while the transport case is loaded at a load/unload system of a semiconductor process tool. The sensor system generates sensor data indicative of conditions at the transport case upon arrival at the load/unload system and while a robot arm unloads and loads the wafers from the transport case. The transport case also includes a communication system that can transmit sensor data or other alerts to an external control system so that the external control system can take action to prevent damage to wafers based on the sensor data.

The wafer transport case in accordance with embodiments of the present disclosure provides several benefits. The sensor system can detect that wafers or the transport case itself are in a position that could result in damage to the wafers if not addressed. The sensor system can detect misalignment or other risk factors that are present during loading and unloading of wafers. The wafer transport case can transmit sensor data to the external control system so that the external control system can take steps to correct alignment or positioning issues prior to transporting the transport case, unloading wafers, or loading wafers. This ensures that semiconductor wafers and other sensitive equipment are not damaged during transport, loading, or unloading. The result is better functioning integrated circuits and improved wafer yields.

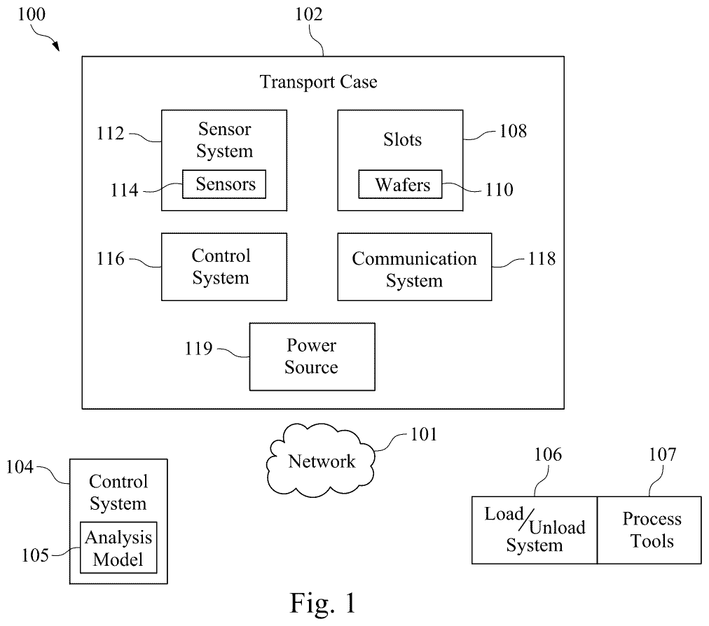

FIG. 1 is a block diagram of a semiconductor processing system 100, in accordance with some embodiments. The semiconductor processing system 100 includes a transport case 102, a control system 104, and a load/unload system 106. As will be set forth in more detail below, the components of the semiconductor processing system 100 cooperate to ensure that semiconductor wafers are safely stored, transported, loaded, and unloaded in conjunction with the transport case 102.

In some embodiments, the transport case 102 is a wafer transport case configured to hold semiconductor wafers 110 before, after, or between semiconductor processes. The transport case 102 includes a plurality of slots 108. Each of the slots 108 is configured to receive and hold a wafer 110. Wafers 110 can be loaded into or unloaded from the transport case 102. Wafers 110 can be transported in the transport case 102, as will be described in more detail below.

In some embodiments, the transport case 102 is a FOUP. The FOUP includes a front cover that can be removed to expose the slots 108. When the front cover is removed, wafers 110 can be loaded into the slots 108 or unloaded from the slots 108. After unloading/loading, the front cover can be replaced. As will be set forth in more detail below, the front cover may include pin slots configured to receive pins from the load/unload system 106. The load/unload system 106 removes or replaces the front cover with the pins positioned in the pins slots.

In some embodiments, the transport case 102 includes pin slots on a bottom surface. When the transport case 102 is brought to a process tool, the transport case 102 is placed on a load port. The load port can include a plurality of bottom pins configured to hold the transport case firmly in alignment for unloading of wafers for processing by the process tool, or for loading of wafers to be processed by the process tool. The pin slots on the bottom surface of the transport case are configured to receive the bottom pins of the load port.

The semiconductor processing system 100 processes semiconductor wafers 110. The semiconductor wafers 110 undergo a large number of semiconductor processes in order to form integrated circuits within the semiconductor wafers. The semiconductor processes can include forming transistors on a semiconductor substrate within the semiconductor wafers, forming dielectric layers on the semiconductor wafers, forming metal interconnects on the semiconductor wafers, and other processes to form structures and components within the semiconductor wafers. Some of the processes associated with forming the features can include epitaxial growth processes, thin film deposition processes, etching processes, photolithography processes, chemical mechanical planarization (CMP) processes, annealing processes, ion implantation processes, cleaning processes, dicing processes, and various other processes.

The semiconductor processing system 100 may include a plurality of process tools 107 for performing the semiconductor processes on the wafers 110. Examples of process tools can include photolithography tools, thin-film deposition tools, etching tools, aligning tools, annealing tools, ion implantation tools, CMP tools, or other types of tools.

During the processing cycle of a wafer 110, a wafer may be loaded into a transport case 102. The transport case 102 may then be transported to a process tool 107 for a first processing step. The process tool 107 includes or is coupled to a load/unload system 106. The transport case 102 is positioned at a load/unload port of the load/unload system 106. The load/unload system 106 removes a front cover from the transport case 102. A robot arm of the load/unload system 106 then removes the wafer 110 and places the wafer 110 in the first process tool 107. The process tool 107 then performs a first semiconductor process on the wafer. During the process, the transport case 102 remains open. As a result, the humidity inside the transport case during the process is crucial for the remaining wafers inside the transport case.

After the first semiconductor process has been performed on the wafer 110, the load/unload system 106 loads the wafer 110 back into the transport case 102. In practice, the load/unload system 106 may load the wafer 110 into a different transport case 102. The transport case 102 may then be transported to a second semiconductor tool for a next processing step. Alternatively, the transport case 102 may be transported to a lot of storage site and the wafer 110 may be loaded into a stocker. Subsequently, the wafer 110 is unloaded from the stocker into a transport case 102 and transported to a next semiconductor process tool 107.

Due to the sensitivity of the wafer 110, it is very beneficial to ensure that no damage or contamination occurs during transport, unloading, and loading. It is possible that damage can occur during loading of a wafer into the transport case 102, during transport of the wafer 110 in the transport case 102, or during unloading of the wafer 110 from the transport case 102.

In order to reduce or prevent the risk of damage to wafers 110, the transport case 102 includes a sensor system 112. The sensor system 112 monitors the loading of wafers into the transport case 102, monitors the orientation of the wafer is in the transport case 102, monitors the unloading of wafers from the transport case 102, and monitors the orientation of the transport cases 102 itself.

In some embodiments, the sensor system 112 includes a plurality of sensors 114 within or on the transport case 102. The sensors 114 can perform a variety of functions, as will be set forth in more detail below. The sensors 114 can monitor a tilt of the wafer 110 within a slot 108. The sensors 114 can monitor whether an edge of the wafer 110 has collided with a frame of a slot 108. The sensors 114 can monitor whether a wafer 110 is centered within a slot 108. The sensors 114 can monitor whether a wafer during loading is on a trajectory to collide with a frame of a slot 108. The sensors 114 can monitor whether the transport case 102 itself is tilted prior to or during transport or loading/unloading. The sensors 114 can monitor the position and orientation of door removal pins of the load/unload system 106 prior to or during removal of the front cover of the transport case 102. The sensors 114 can perform other types of functions than those described above without departing from the scope of the present disclosure.

In some embodiments, the transport case 102 includes a control system 116. The control system 116 can include one or more processors and one or more memories. The control system 116 can control the sensor system 112. The control system 116 can receive sensor data from the sensor system 112 and can process the sensor data in order to determine whether the sensor data indicates pin misalignment, a collision, a bad orientation, tilting, or other issues associated with the transport case 102 and the wafers 110 within the transport case 102. While the control system 116 is shown as separate from the sensor system 112, in practice, the control system 116 may be part of the sensor system 112.

In some embodiments, the transport case 102 includes a communication system 118. The communication system 118 can include one or more wireless transceivers configured to transmit data from the transport case 102. The communication system can also include wired communication systems for transmitting data in a wired manner from the transport case 102. The control system 116 may control the transmission of data from the communication system 118. The control system 116 may also control or monitor the reception of data via the communication system 118.

In some embodiments, the transport case 102 includes a power source 119. The power source 119 can include a battery that supplies power to the sensor system 112, the control system 116, and the communication system 118. The power supply can be rechargeable. Accordingly, the transport case one or two may include one or more power ports configured to connect to a charging cable to charger recharge the power source one 19. Other types of power sources can be utilized without departing from the scope of the present disclosure.

The control system 104 can correspond to a control system associated with the semiconductor processing system 100. The control system 104 can include processors, memories, and communication systems. The control system 104 may be associated with a particular semiconductor process tool 107 and may control the function of the semiconductor process tool 107 including controlling the function of a load/unload system 106 associated with a semiconductor process tool 107. The control system 104 may be associated with a transport system that carries the transport case 102 between processing tools 107 or storage sites. The control system 104 may correspond to a general control system that controls a plurality of processing tool 107 or transport systems of the semiconductor processing system 100.

The control system 104 may correspond to a dispersed control system. Portions of the control system may be located at various locations within the semiconductor processing system 100. Portions of the control system 104 may be virtual resources or cloud-based resources external to the physical processing facility associated with the semiconductor processing system 100. Accordingly, processing resources, memory resources, and communication resources of the control system 104 may be dispersed within the semiconductor processing system 100.

The control system 116 of the transport case 102 may control the communication system 118 to transmit data associated with the transport case 102 to the control system 104. The communication system 118 may continuously transmit data associated with the status of the transport case 102 or the wafers 110 carried by the transport case 102 during transport, loading, or unloading of wafers 110.

In some embodiments, the communication system 118 may transmit data to the control system 104 when an alert or warning is to be issued to the control system 104. For example, the control system 116 of the transport case 102 may transmit an alert to the control system 104 when the sensor data indicates that a wafer 110 is tilted, that an edge of a wafer 110 has collided with a frame of a slot 108, that a wafer 110 is not centered within a slot 108, that the transport case 102 is tilted, that pins of a load/unload system 106 are misaligned with corresponding pins slots in a door of the transport case 102, or other types of alerts.

The control system 104 can control or adjust an aspect of the transport case 102 responsive to the data or alerts received from the transport case 102. For example, the control system 104 can control the robot arm to remove a tilted wafer, to adjust a position of a tilted or poorly centered wafer, to remove a wafer that has experienced a collision, to adjust a position of a tilted transport case 102, to stop transport of a transport case 102, to transfer the transport case 102 to an analysis tool so that wafers may be analyzed in response to possible damage. The control system 104 may issue an alert to technicians to manually inspect or adjust aspects of the transport case 102. Accordingly, the control system 104 may take various actions responsive to the alerts or data received from the transport case 102.

The transport case 102, the control system 104, and the load/unload system 106 may be communicatively coupled together via a network 101. The network 101 can include a wireless network, a wired network, a combination of wireless and wired networks, or other types of networks that can facilitate communication between the components of the processing system 100.

In some embodiments, control system 104 includes an analysis model 105. The analysis model 105 can receive sensor signals from the sensor system 112 of the transport case 102. The analysis model 105 can analyze the sensor signals to determine whether or not there are faults present at the transport case 102. A fault can include misalignment of door pins of a load/unload system 106 configured to mate with a door of the transport case 102 for removal of the door of the transport case 102. A fault can include misalignment of bottom pins for of a load/unload system 106. A fault can include tilting of a transport case 102. A fault can include tilting of a wafer 110 within the transport case 102. A fault can include unsafe levels of humidity within the transport case 102. A fault can include collision of a wafer 110 with a surface within the transport case 102. A fault can include misalignment of the robot arm attempting to load or unload a wafer 110. A fault can include gaps between slots 108 that are either too large or too small. Various other types of faults can be detected by the analysis model 105 based on the sensor data.

In some embodiments, the analysis model 105 can pause operation of a load/unload system 106 based on detection of a fault condition from the sensor signals 112. The analysis model 105 can cause a robot arm to stop loading or unloading of a wafer 110. The analysis model 105 can prevent removal of a door of the transport case 102 until a fault condition is resolved. The analysis model 105 can reenable loading/unloading or transporting of the transport case 102 upon resolution of the fault condition. The analysis model 105 can control robot arms or other transport or load/unload components to avoid harm to a wafer 110.

In some embodiments, the analysis model 105 is trained with a machine learning process to analyze the sensor data provided by the transport case 102. The analysis model can be trained to analyze sensor data indicating wafer leveling and/or capping at the load port, wafer centering of the front of the robot arm, wafer collision, load port leveling, temperature, humidity, and pressure within the group, pin position check at the load port stage, and other factors. The analysis model 105 can be trained to determine whether an automatic shutdown of transfer/transport operations should occur, whether automatic adjustment of a robot arm or other component should occur, or whether there are no faults and operation should continue as normal.

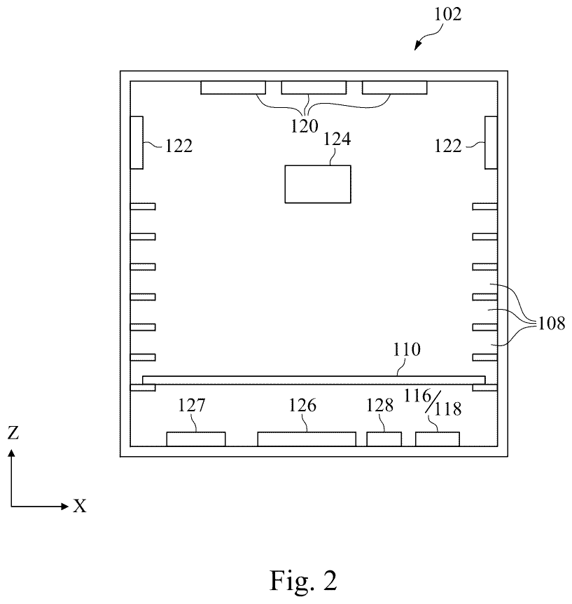

FIG. 2 is a front view of a transport case 102, in accordance with some embodiments. The transport case 102 of FIG. 2 is one example of a transport case 102 of FIG. 1. The transport case 102 includes a front opening 121. Though not shown in FIG. 2, the transport case 102 may include a removable cover or door that is placed in the front opening 121. The removable cover or door can be temporarily removed when wafers are loaded into the transport case 102 or when wafers are unloaded from the transport case 102. The removable door cover can then be replaced when loading/unloading is complete. Further details regarding aspects of the removable door will be provided below.

The transport case 102 includes a plurality of slots 108. In the example of FIG. 2, each slot 108 includes a first portion on a first lateral side of the of the transport case 102 and a second portion on a second lateral side of the transport case 102. When a wafer 110 is positioned in a slot 108, the wafer 110 rests on the first portion and the second portion of the slot 108.

FIG. 2 illustrates a single wafer 110 in the bottom slot 108. However, in practice, a plurality of wafers 110 may be stored in the transport case 102. Each wafer 110 may be positioned in a respective slot 108. For example, a plurality of wafers may be loaded into the slots 108. The transport case 102 may be transported by an overhead track or other transport system to a next process tool 107. A load/unload system 106 of the process tool 107 may then remove the front cover and a robot arm may unload the wafers 110 from the transport case 102 into the process tool 107.

In FIG. 2, the transport case 102 includes a plurality of sensors. In particular, the transport case 102 includes sensors 120, 122, 124, 126, 127, and 128. The sensors are examples of sensors 114 of a sensor system 112 from FIG. 1. In practice, other sensors may be positioned in the transport case 102. Sensors may be positioned differently than shown in FIG. 2.

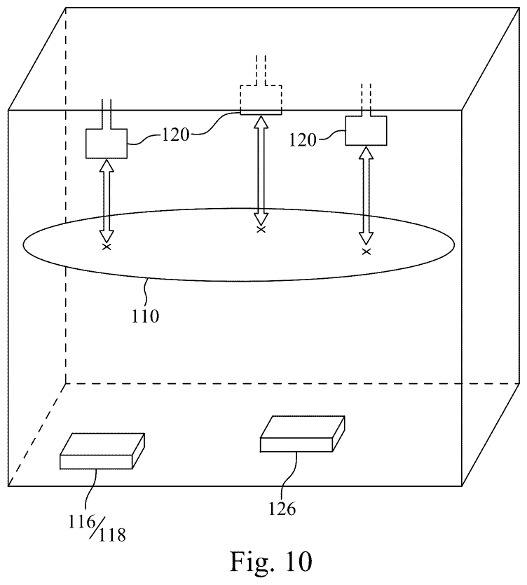

In some embodiments, the sensors 120 correspond to distance sensors. The distance sensors may each be configured to measure a vertical distance between the surface of a wafer 110 and the corresponding sensor 120. In an example in which three distance sensors are present, the three distance measurements can be utilized to determine a tilt of the wafer 110, as will be described in more detail in relation to FIG. 10. In some embodiments, the sensors 120 can detect wafer warpage as indicated by differences in distance to wafer center vs distance to wafer edge. The warpage can indicate tensile or compressive stress.

In some embodiments, the sensors 122 may correspond to inertial sensors. The inertial sensors can include multiaxis accelerometers, multiaxis gyroscopes, or other types of inertial sensors. The inertial sensors can sense, based on vibrations or accelerations, whether a wafer 110 has impacted a frame of a slot 108. The sensors 122 may include other types of sensors that can detect vibrations or impacts. The inertial sensors may be positioned differently than shown in FIG. 2. Furthermore, the transport case 102 may include a large number of inertial sensors each coupled to a respective slot 108 or portion of a slot 108. This can assist in detecting whether a particular wafer has impacted a frame of a particular slot 108.

The sensors 124 may correspond to cameras or other types of image sensors. The sensors 124 can include charge coupled devices. The sensors 124 can capture images of the wafers 110 within slots 108. The sensors 124 can generate sensor signals that indicate how centered a wafer 110 is within a slot 108, as will be described in more detail below. In some embodiments, the sensors 124 may capture images of a wafer 110 each time a wafer 110 is loaded into a slot 108. The sensors 124 can be mounted within the transport case 102. A different number of sensors 124 can be included in the transport case 102.

In some embodiments, the sensor 126 may correspond to a leveling sensor. The leveling sensor 126 may detect whether the transport case 102 is tilted or not. The leveling sensor can one or more inertial sensors or gravitational sensors that detect whether a horizontal X-axis and a horizontal Y-axis or both mutually orthogonal to a vertical Z-axis. If the X-axis and the Y-axis are not both orthogonal to the direction of gravity (Z-axis), then the transport case is tilted. Tilting of the transport case during transport or at the load/unload port of the load/unload system 106 can result in damage to the wafers 110. Accordingly, the control system 116 can control the communication system 118 to output an alert that the transport case 102 is tilted. The control system 104 can then take steps to address the tilting. This can include stopping transport, loading, or unloading of the wafers 110. The control system 104 can also output an alert to a technician to adjust or inspect the transport case 102.

The sensor 127 can correspond to one or more sensors to sense environmental conditions within the transport case 102. For example, the sensor 127 can include a humidity sensor that senses the humidity within the transport case 102. The sensor 127 can include a temperature sensor that senses a temperature within the transport case 102. The sensor 127 can include a pressure sensor that senses air pressure within the transport case 102. The transport case 102 can transmit pressure, temperature, and the humidity data to the control system 104. The control system 104 can adjust the temperature, humidity, or air pressure within the transport case 102 or can stop a transfer/transport operation based on abnormal temperature, humidity, or air pressure measurements.

In some embodiments, the sensor 128 is configured to detect debris falling from a backside of wafer 110. In some embodiments, the sensor 128 detects debris by detecting vibrations or material accumulations that are indicative of debris falling from a wafer 110. Once debris is detected, an optical camera or other type of image capture device (such as the cameras 124 or other devices) can inspect the front side of a wafer 110 in response to detection of the debris. The sensor 128 can include multiple sensors and can be positioned at locations other than shown in FIG. 2. In some embodiments, one or more of the previously described sensors can assist in detecting debris.

Various other types of sensors or various other arrangements of sensors can be implemented within the transport case 102 without departing from the scope of the present disclosure.

In some embodiments, the control system 116 and the communication system 118 are positioned near a bottom of the transport case 102. The control system 116 may receive sensor data from the various sensors. The control system 116 may receive sensor data from the sensors via wired connections (not shown) or via wireless connections. The control system 116 may process the sensor data and an may control the communication system 118 to output data to the external control system 104 as described previously. The control system 116 and the communication system 118 can be positioned or arranged in other ways without departing from the scope of the present disclosure.

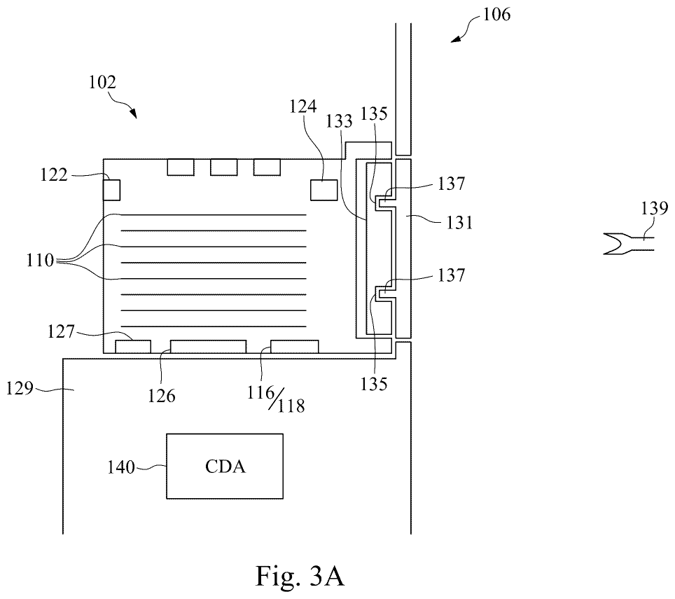

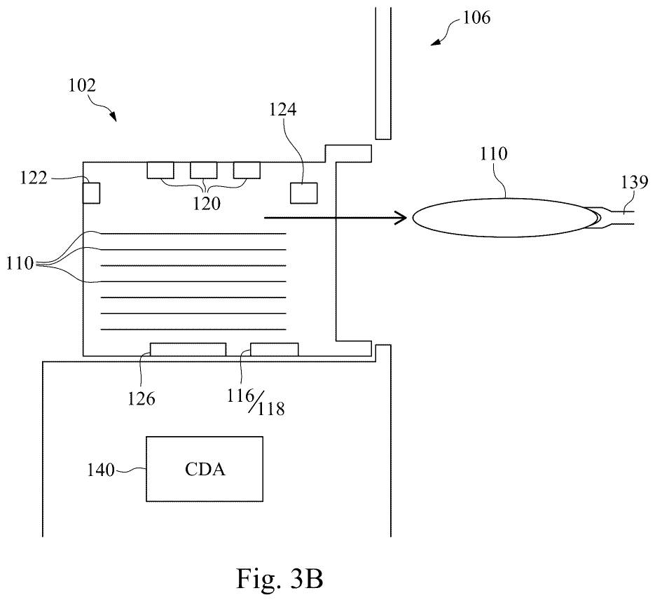

FIG. 3A is a side view of a wafer transport case 102 at a load/unload stage 129 of a load/unload station 106, in accordance with some embodiments. The load/unload stage 129 can be a load/unload port at a semiconductor process tool 107, as described previously.

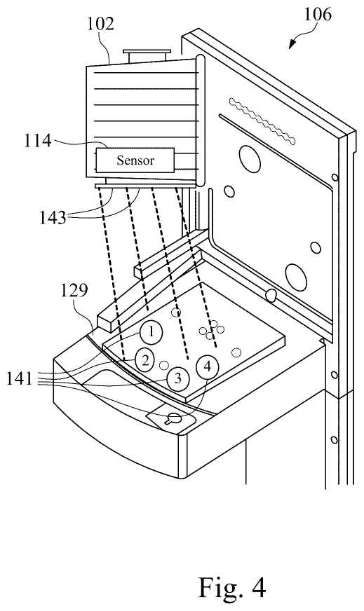

When the transport case 102 arrives at the load/unload stage 129, the transport case 102 is positioned in front of the stage 129. A front cover 133 is positioned at the front of the transport case 102. The front cover 133 includes pin slots 135 that enable removal of the front cover 133. Though not shown in FIG. 3A, in some embodiments the stage 129 can include bottom pins 141 (see FIG. 4) configured to mate with bottom slots of the transport case 102.

The load/unload stage 129 includes a front cover removal device 131. The front cover removal device 131 is configured to remove the front cover 133 of the transport case 102. In particular, the front cover removal device 131 includes pins 137. The pins 137 are configured to be positioned within the pin slots 135 of the front cover 133. The pins 137 mate with the slots 135. The front cover removal device 131 then removes the front cover 133 of the transport case 102 so that wafers 110 can be unloaded from (or loaded into, as the case may be) the transport case 102 by a robot arm 139.

The transport case 102 includes sensors 124 that monitor the alignment of the pins 131 with the slots 137. If the alignment is not proper, then removal of the front cover 133 may fail. Alternatively, if alignment is not proper, removal of the front cover 133 may cause jarring of the transport case 102, this can possibly damage wafers 110.

Accordingly, the sensors 124 measure or detect the positioning or alignment of the pins 131 relative to the pin slots 135. If there is misalignment, the control system 116 can control the communication system 118 to output an alert or alignment data to the control system 104. The control system 104 can then adjust either the position of the transport case 102 relative to the unload/unload stage 129 or can adjust the position of the front cover removal device 131 so that the pins 137 are better aligned with the pin slots 135.

In some embodiments, the sensors 124 correspond to image sensors or other types of ranging sensors that can sense the alignment or position of the pins 137 within the slots 135. The sensors 124 may be moved into position to sense the alignment of the pins when the transport case 102 arrives at the load/unload stage 129. Other types of sensors can be utilized without departing from the scope of the present disclosure.

In some embodiments, the stage 129 includes a clean dry air (CDA) supply 140. The clean dry air supply 140 can assist in maintaining or adjusting a desired humidity or other environmental conditions within the transport case 102. The clean dry air supply 140 can be positioned other than shown in FIG. 3A. The clean dry air supply 140 can supply clean and dry air into the interior of the transport case 102. This can be accomplished via one or more fluids channels (such as the fluid channels 145 and 147 of Figure) coupled to the transport case 102 when the transport case 102 is mounted on the stage 129. Alternatively, this can be accomplished by flowing clean and dry air into an open front of the transport case 102 or into another aperture of the transport case 102.

In some embodiments, the clean dry air supply 140 can continuously supply clean and dry air into the transport case 102. Alternatively, in some embodiments, the clean dry air supply 140 can supply clean dry air into the transport case 102 in response to a condition detected by the sensors 127. For example, if the sensors 127 detect a level of humidity that is higher than a threshold humidity, then the clean dry air supply 140 can automatically supply clean and dry air into the transport case 102 to reduce the humidity to a specified level. In some embodiments, the clean dry air supply 140 can supply clean dry air into the transport case 102 to assist in removing dust or other particles.

In FIG. 3B, the front cover 133 has been removed by the cover removal device 131. The robot arm 139 is unloading a wafer 110 from the transport case 102. The sensors 124 have been moved so that the wafers 110 can be freely accessed by the robot arm 139. After all of the wafers 110 have been loaded, the front cover removal device 131 can replace the front cover 133 onto the transport case 102.

FIG. 4 is an illustration of a transport case 102 and a load/unload system 106 during a process of placing the transport case 102 on the stage 129, in accordance with some embodiments. FIG. 4 illustrates bottom pins 141 on the stage 129. The transport case 102 includes bottom slots 143. The bottom slots 143 are configured to mate with the bottom pins 141 to securely hold the transport case 102 in position on the stage 129. Prior to placement of the transport case 102 on the stage 129, one or more sensors 114 detects the position and alignment of the bottom pins 141 with respect to the bottom slots 139. If the bottom pins 141 are not aligned with the bottom slots 139, then the control system 104 can receive such sensor signals and can adjust a position of the transport case 102 prior to placing the transport case 102 on the stage 129. This can help ensure that there is no jostling of the transport case 102 during the process of placing the transport case 102 on the stage 129.

The sensor 114 of FIG. 4 can correspond to one or more cameras or image sensors, such as sensors 124. The sensors 114 may be positioned within the transport case 102 and may capture images of the bottom pins 141 via apertures or transparent locations on a bottom of the transport case 102. In some embodiments, cameras can be placed in the bottom slots 143. Cameras can be placed external to the transport case 102, in some embodiments.

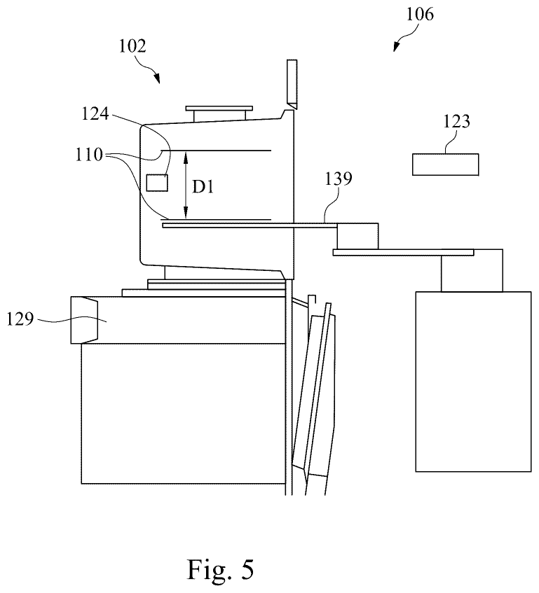

FIG. 5 is an illustration of a transport case 102 positioned on a stage 129 of a load/unload system 106. The door has been removed and a robot arm 139 is unloading a wafer 110 from the transport case 102. An image sensor 124 senses a distance D1 between two wafers 110 within the transport case 102. This distance data is provided to the control system 104. The control system 104 can then control the robot arm 139 to remove wafers 110 based on the measured distance. In some embodiments, the control system 104 can provide the distance data to the load/unload system 106 which can then control the robot arm 139. In some embodiments, the transport case 102 may transmit the distance data directly to the load/unload system 106.

At this stage, the transport case 102 can also generate sensor data related to the loading or unloading of wafers by the robot arm 139. For example, the image sensor 124 or other sensors can generate sensor data indicating whether or not the wafer 110 is centered within a slot 108. The sensors 122 can generate sensor data indicating whether or not a collision is occurred between the wafer 110 and the slot 108. The sensors 120 can determine whether the wafer 110 is level. All of the sensor data can be transmitted to the control system 104 or to the load/unload system 106 to stop or adjust the load/unload operation based on the sensor data.

In some embodiments, the load/unload system 106 includes a sensor 123. The sensor 123 can be coupled to the robot arm 139 or can be positioned adjacent to the robot arm 139. The sensor 123 can include multiple sensors that can sense the vibrations corresponding to the wafer 110 impacting a frame 130 during loading or unloading with the robot arm 139, centering of the wafer during loading or unloading with the robot arm 139, or a gap between wafers within the transport case 102 during loading or unloading with the robot arm 139.

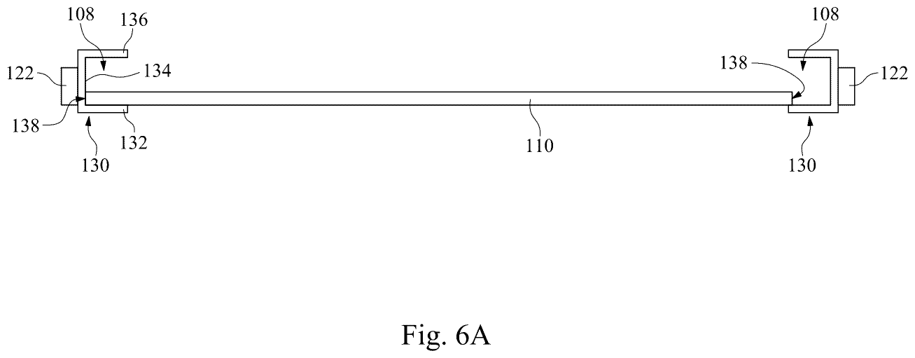

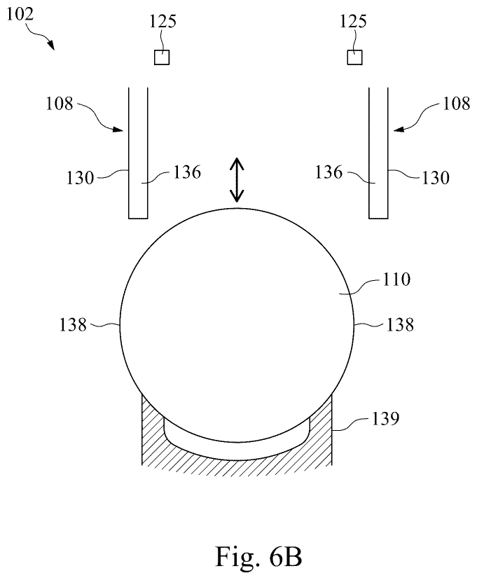

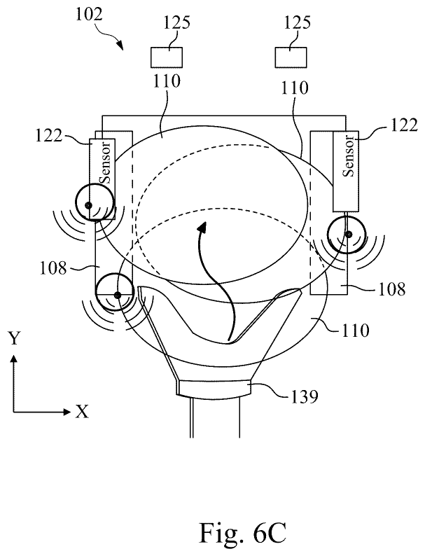

FIG. 6A is a side view of a portion of a transport case 102 in accordance with some embodiments. Only a single slot 108 and a single wafer 110 are shown. The slot 108 includes a frame 130. The frame includes a bottom surface 132, an interior side surface 134, and a top surface 136. In practice, the top surface 136 may correspond to the bottom portion of a next higher slot 108. The wafer 110 includes a lateral edge 138.

Inertial sensors 122 are coupled to the frame 130 of the slot 108. In practice, the inertial sensors 122 may be positioned in a different manner than shown in FIG. 6A. The inertial sensors 122 can detect whether the edge 138 of the wafer 110 has impacted the side surface 134 of the frame 130. In the example of FIG. 6A, the lateral edge 138 of the wafer 110 has contacted or collided with the side surface 134 of the frame 130 of the slot 108. The left inertial sensor 122 generates sensor data indicative of the collision. The sensor system 112, or the control system 116, can determine that a collision has occurred based on the sensor data. The control system 116 can then control the communication system 118 to output an alert indicating that the collision has occurred.

The control system 104 receives the collision alert and can take action responsive to the collision alert. The control system 104 may immediately stop transport of the transport case 102, may stop loading or unloading of wafers 110, or may cause a robot arm of the load/unload system 106 to adjust a position of the wafer 110. In some embodiments, the control system 104 may cause the transport system to transport the transport case 102 to an inspection station inspection tool to determine whether damage has occurred to the wafer 110. The control system 104 commission alert to a technician to manually inspect the wafer 110. This can help ensure that a damage control inspection is performed prior to a next processing step. If damage is detected, then the wafer can be scrapped prior to wasting additional processing steps. FIG. 6B is a top view of a portion of a transport case 102 during loading of the wafer 110 into the transport case 102, in accordance with some embodiments. FIG. 6B illustrates a portion of a single slot 108. In particular, a top portion of a frame 130 is shown in FIG. 6B. A robot arm 139 of the load/unload system 106 is carrying the wafer 110 into the slot 108.

Sensors 125 are positioned within the transport case 102. The sensors 125 monitor a trajectory of the wafer 110 during loading. The sensors 125 can detect whether the trajectory of the loading process is aligned to cause a collision of the lateral edge 138 with the frame 130. If the alignment corresponds to a collision trajectory, then the control system 116 can control the communication system 118 to output an alert to the control system 104. The control system 104 can control the robot arm 139 to adjust his position or alignment to avoid the collision. The loading process can then continue safely.

The sensors 125 can include image sensors that capture images or otherwise monitor the position of the wafer 110 during loading. The sensors 125 can be positioned other than shown in FIG. 6B. In some embodiments, the sensors 125 can include arranging sensors or other types of sensors. In some embodiments, the sensors 125 can move vertically as additional wafers 110 are loaded into the transport case 102 so that the sensors are in position to measure the alignment or trajectory or orientation of each wafer 110 is the wafer is loaded. Various other configurations or sensor types can be utilized without departing from the scope of the present disclosure.

FIG. 6C is a top view of a transport case 102 during an unloading process of a wafer 110 with a robot arm 139, in accordance with some embodiments. FIG. 6C illustrates a top wafer 110 that is not centered and is colliding or nearly colliding with a left side of a slot 108. FIG. 6C illustrates a metal wafer that is not centered and is colliding or nearly colliding with a right side of a slot 108. A bottom wafer 110 is currently being removed by the robot arm 139. The sensors 122 can sense collisions of the wafers 110 with the slots 108. Sensors 125 can determine whether or not a wafer being removed is centered. Based on the sensor signals, the robot arm 139 can adjust its course to help ensure that the wafer 110 does not collide with or otherwise jostle any part of the transport case 102. The control system 104 or the load/unload system 106 can control, stop, or adjust the robot arm 139.

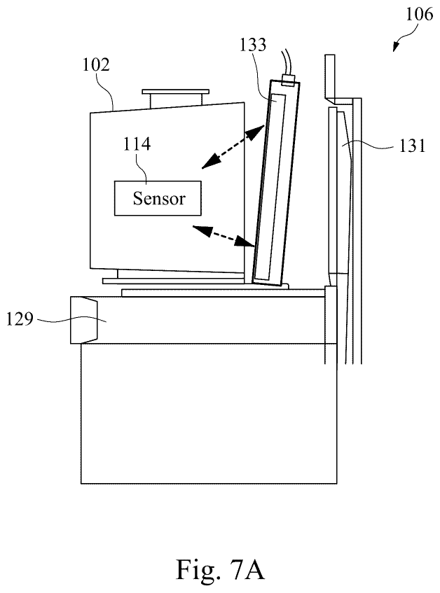

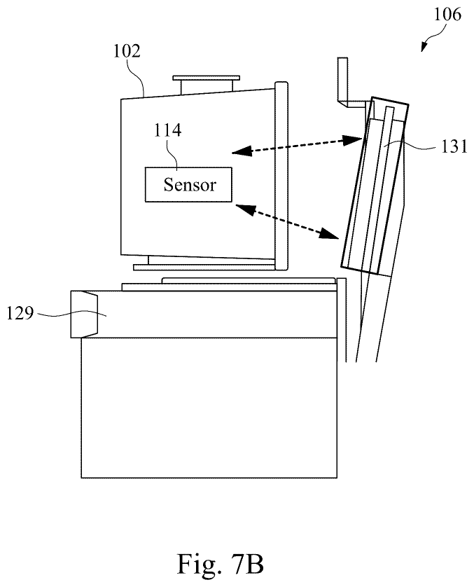

FIG. 7A is an illustration of a transport case 102 at a load/unload system 106, in accordance with some embodiments. In FIG. 7A, a sensor 114 of the transport case 102 senses whether or not the front door 133 is slanted. One or more distance sensors or image sensors can detect that the distance of a bottom portion of the front door 133 is different than the distance to the top portion of the door 133. This can indicate tilting of the door 133. When such tilting is detected, the control system 104 can adjust the load/unload system 106 to safely remove the front door 133 without jostling the transport case 102. This can include adjusting in alignment of the door removal device 131 during removal. In some embodiments, the control system 104 can stop removal of the front door 133 until proper alignment has been achieved.

In FIG. 7B, the door removal tool has removed the front door or is returning the front door 133 to the transport case 102. The sensors 114 can detect whether the door removal tool 131 is tilted. The control system 104 can adjust the load/unload system 106 to safely remove the front door that jostling the transport case 102. In some embodiments, the control system 104 can stop return of the front door 133 by the door removal tool 131 until proper alignment has been achieved.

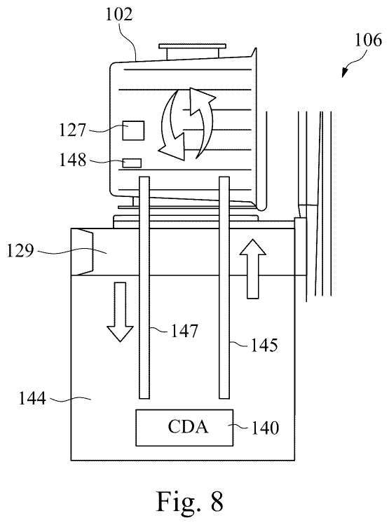

FIG. 8 is an illustration of a transport case 102 positioned at a load/unload system 106, in accordance with some embodiments. The transport case 102 rests on a stage 129. A base 144 below the stage 129 includes the clean dry air supply 140 and tubes or channels 145 and 147 coupled to the clean dry air supply 140. When the transport case 102 is mounted on the stage 129, the tubes or channels 145 and 147 can be communicatively coupled with an interior of the transport case 102. In some embodiments, the tubes or channels 145 and 147 can be introduced into the transport case 102 by being raised through apertures in the stage 129 and in the transport case 102. In some embodiments, the tubes or channels 145 and 147 can protrude from the bottom pins 141 into apertures in the bottom slots 143.

In some embodiments, the tube or channel 145 is an inlet tube by which fluids can be flowed into the interior of the transport case 102. The fluids can include molecular nitrogen, air, argon, or other fluids. In some embodiments, the tube or channel 147 is an outlet tube by which fluids can be flowed out of the interior of the transport case 102.

In some embodiments, a plurality of sensors 127 are positioned within the interior of the transport case 102. As described previously, the plurality of sensors 127 can include a temperature sensor, a humidity sensor, and the pressure sensor. In some cases, it may be desirable for the temperature, humidity, and pressure to be maintained within selected ranges. Accordingly, the tubes 145 and 147 can be utilized to adjust the pressure, temperature, and humidity within the transport case 102. For example, if the community is higher than an upper humidity threshold, then a drive fluid can be flowed into the transport case 102 to reduce the humidity. Alternatively, if the humidity is below a lower humidity threshold, then humid air can be flowed into the transport case 102 to increase the humidity. Likewise, if the pressure falls below a lowered pressure threshold or rises above the upper pressure threshold, then the air pressure can be adjusted via the tubes 145 and 147. Likewise, if the temperature falls below a lower temperature threshold or rises above a high temperature threshold, then the temperature can be adjusted by flowing a cooler or hotter fluid into the transport case 102.

The sensors 127 can output sensor signals indicative of the humidity, pressure, and temperature. These values can be transmitted to the control system 104. The control system 104 can then control the load/unload system 106 to make adjustments to the temperature, pressure, or humidity via the tubes 145 and 147.

In some embodiments, the transport case 102 includes one or more temperature sensors 148. The one or more temperature sensors 148 can be positioned on, coupled to, or positioned adjacent to the slots 108. In some embodiments, the temperature sensors 148 sense the temperature of wafers 110 positioned on the slots 108 after a semiconductor process. In some cases, the wafers 110 may have elevated temperatures after a semiconductor process has been performed on. The temperature sensors 148 generate sensor signals indicative of the temperature of the wafers 110. The temperature sensors 148 can be positioned other than shown in FIG. 8.

In some embodiments, the elevated temperature of wafers 110 may result from a fault condition in a processing tool. Accordingly, in some embodiments, if the temperature sensors 148 sense that the temperature of the wafers is greater than a threshold temperature, then the clean dry air supply 140 can be activated to cool down the wafers 110 by flowing a cool air into the transport case 102. In some embodiments, the control system 116 may control the communication system 118 to output a warning signal to shut down the process tool and to output a notification to a technician to inspect the process tool based on the temperature exceeding the threshold value.

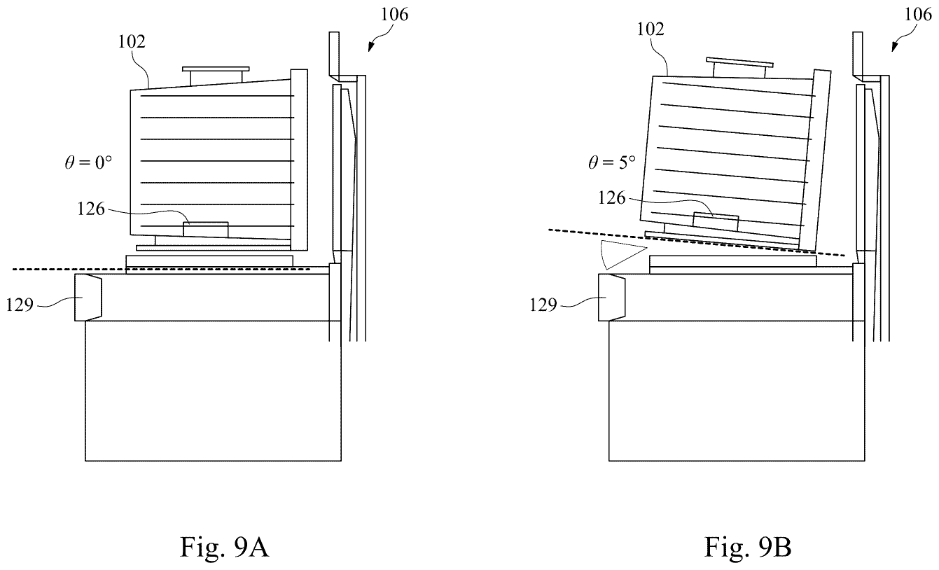

FIGS. 9A and 9B are illustrations of a transport case 102 and a load/unload system 106, in accordance with some embodiments. In FIG. 9A, the transport case 102 is positioned on the stage 129. The sensor 126 detects that the transport case 102 is level of the state. The sensor data from the sensor 126 is provided to the control system 104 and loading/unloading is enabled to proceed.

In FIG. 9B, the sensor 126 detects that the transport case 102 is not level. The sensor data is provided to the control system 104. The control system 104 can stop the load/unload process in response to the sensor data indicating that the transport case 102 is not level. The control system can adjust the transport case 102 to level the transport case 102 in response to the sensor data. Alternatively, the control system 104 can output an alert for technician to adjust the stage 129 or transport case 102 to ensure that the transport case 102 is level.

FIG. 10 is an illustration of a transport case 102, in accordance with some embodiments. The transport case 102 of FIG. 10 is one example of a transport case 102 of FIGS. 1 and 2. In FIG. 10, sensors 120 are each measuring a vertical distance between the sensor 120 and a particular point x on the surface of the wafer 110. The three vertical distances can be utilized to determine a tilt of the wafer 110. If the three vertical distances are identical, then the wafer has no tilt. As used herein, no tilt corresponds to the top surface of the wafer 110 lying in a horizontal X-Y plane without a vertical (Z) component. If the three vertical distances are not all identical, then the wafer is tilted.

Each time a wafer 110 is loaded into a slot 108, it is beneficial to monitor whether there is a tilt to the wafer 108. A tilt can be problematic as the wafer 110 may not be in a stable position and may slide or otherwise collide with a frame of a slot 108. A tilt can indicate that there is debris on a bottom surface of the wafer 110 or that there is debris on the frame of the slot 108 on which the wafer 110 rests. A tilt can also indicate that the wafer 110 has been improperly loaded into a slot.

Advantageously, the sensor system 112, utilizing the sensors 120 monitors each wafer 110 when it is loaded into a slot 108 to determine whether a tilt is present. If a tilt is present, or if the tilt exceeds a threshold tilt, then the control system 116 may control the communication system 118 to output an alert to the control system 104 that a wafer is tilted. The control system 104 may then halt loading, unloading, or transport operations so that the tilt can be corrected or otherwise address. This may include alerting a technician to manually inspect the transport case 102 and the wafer 110. This may include transporting the transport case 102 to an inspection tool that may inspect the surface of the wafer or the slot 108 to determine if there is debris, damage, or improper loading of the wafer 110 into the slot 108.

In some embodiments, the wafers 110 are loaded one at a time into the slots 108 in an ascending manner. In other words, if a first wafer is loaded into a first slot 108, a next wafer is loaded into a second slot 108 that is higher than the first slot. If the sensors 120 are positioned above the wafers 110, then this ascending loading enables the sensors 120 can measure the tilt of each wafer 110 as the wafer is loaded into the slot 108.

In some embodiments, the sensors 120 may be positioned at a bottom of the trench port case 102. In this case, the wafers 110 may be loaded in a descending manner such that the sensors 120 may measure the tilt of the bottom surface of each wafer 110 as the wafers are loaded into the transport case 102.

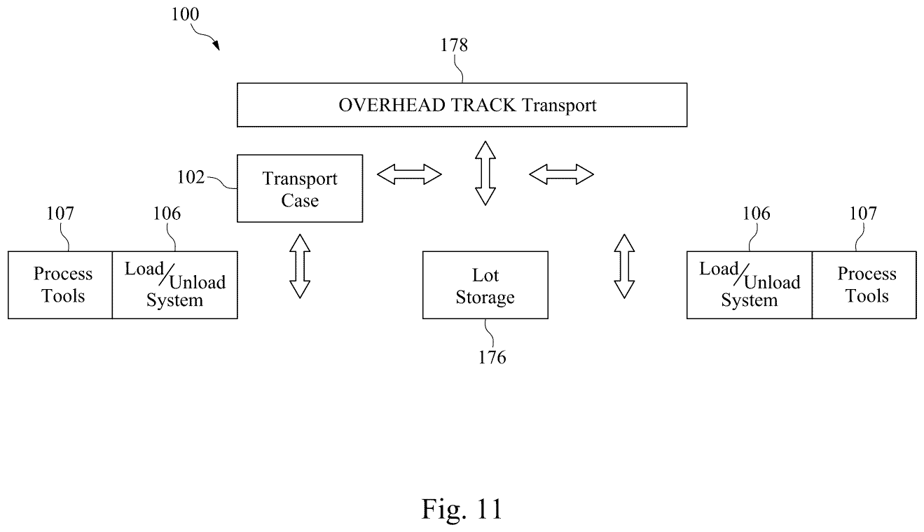

FIG. 11 is a block diagram of a semiconductor processing system 100, in accordance with some embodiments. The semiconductor processing system 100 of FIG. 11 is one example of a semiconductor processing system 100 of FIG. 1. FIG. 11 illustrates two semiconductor process tools 107. A load/unload system 106 is coupled to or as part of each process tool 107. FIG. 11 also illustrates a lot storage 176. The lot storage can include a wafer stocker or other type of storage that can either store transport cases 102 or can store wafers 110 that have been unloaded from transport cases 102 prior to a next semiconductor process.

FIG. 11 illustrates an overhead track transport 178. The overhead track transport 178 is configured to carry transport cases 102 between the process tools 107 or between the lot storage 176 and the process tools 107. In one illustrative example, a transport case 102 is carried by the overhead track transport 178 to a load/unload system 106 of the process tool 107 on the left. Transport case 102 is lowered and positioned at the load/unload system 106. The front cover is removed and the wafers 110 are unloaded from the transport case 102 into the process tool 107. The process tool 107 that performs the first semiconductor process on the wafers 110.

The load/unload system 106 then loads the wafers 110 from the process tool 107 into a transport case 102. This may be the same transport case or different transport case from before. The overhead track transport then carries the transport case 102 to a lot storage 176. The wafers 110 are unloaded from the transport case 102 into a wafer stocker of the lot storage 176. When the wafers 110 are ready for the next semiconductor process, the overhead track carries a transport case 102 to the lot storage 176 and the wafers one loaded into the transport case 102. The overhead track transport 178 then carries the transport case 102 to the load/unload system 106 of the process tool 107 on the right side. The wafers 110 are then unloaded and the second semiconductor process is performed on wafers.

During loading/unloading and transports of the wafers 110 with the transport case 102, the sensor system 112 of the transport case 102 performs the measuring, detecting, and monitoring described previously. The control system 104 can control the components of the system 100 to address or adjust aspects of the transport case 102 responsive to alerts provided by the transport case based on the sensor system 112. Other types of transport systems can be utilized without departing from the scope of the present disclosure.

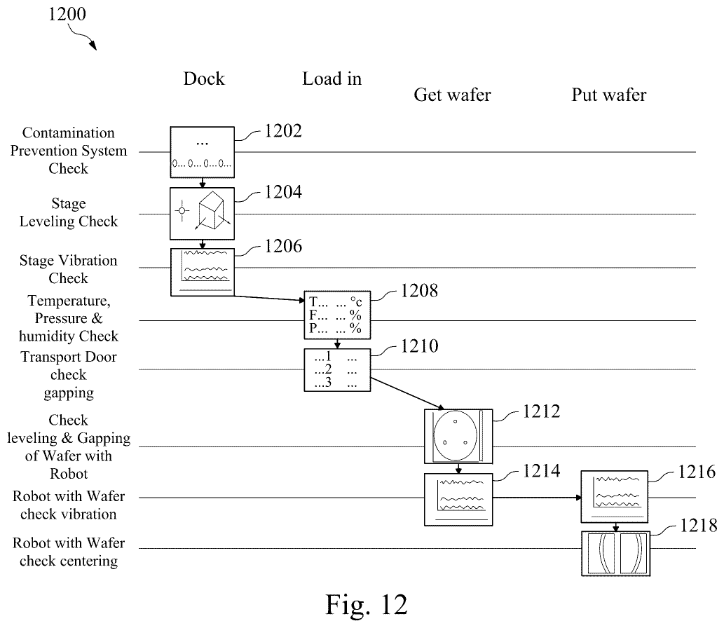

FIG. 12 is a flow diagram of a method 1200, in accordance with some embodiments. The method 1200 can utilize systems, processes, and components described in relation to FIGS. 1-11. At 1202, a transport case 102 is brought to a load/unload station of a process tool. One or more sensors of the transport case 102 checks aspects of a contamination prevention system. This can include checking alignment of bottom pins of the load/unload stage and bottom slots of the transport case, as described previously. At 1204, the method 1200 includes performing a stage leveling check. The stage leveling check can be performed with one or more sensors that detect whether or not the transport case is level, as described previously. At 1206, the method 1200 includes performing a stage migration check with one or more sensors of the transport case. The stage migration check can include detecting whether there are vibrations or collisions while the transport case is on the stage of the load/unload system.

At 1208, a load in operation begins. The loading operation can include detecting temperature, pressure, and humidity of the transport case with one or more sensors of the transport case. At 1210, the loading process includes sensing, with one or more sensors of the transport case, whether there is a gap or tilting of the front door of the transport case.

At 1212, a wafer retrieval process begins in which a robot arm extends into the transport case and retrieves a wafer. One or more sensors of the transport case checks whether the wafer is level on the robot arm. One or more sensors of the transport case also checks the gap between adjacent wafers. At 1214, one or more sensors of the transport case checks whether or not there are vibrations as the robot arm retrieves the wafer.

At 1216, a wafer return process begins. However, between 1214 and 1216, a semiconductor process is performed on the wafer by process tool. After the semiconductor process is performed, the robot arm retrieves the wafer from the process tool and commences an operation to return the wafer to the transport case. Accordingly, at 1216, one or more sensors of the transport case check whether or not there are vibrations as the robot arm places the wafer in the transport case. At 1218, one or more sensors of the transport case checks whether or not the wafer carried by the robot arm is centered with respect to a slot in which the wafer is placed.

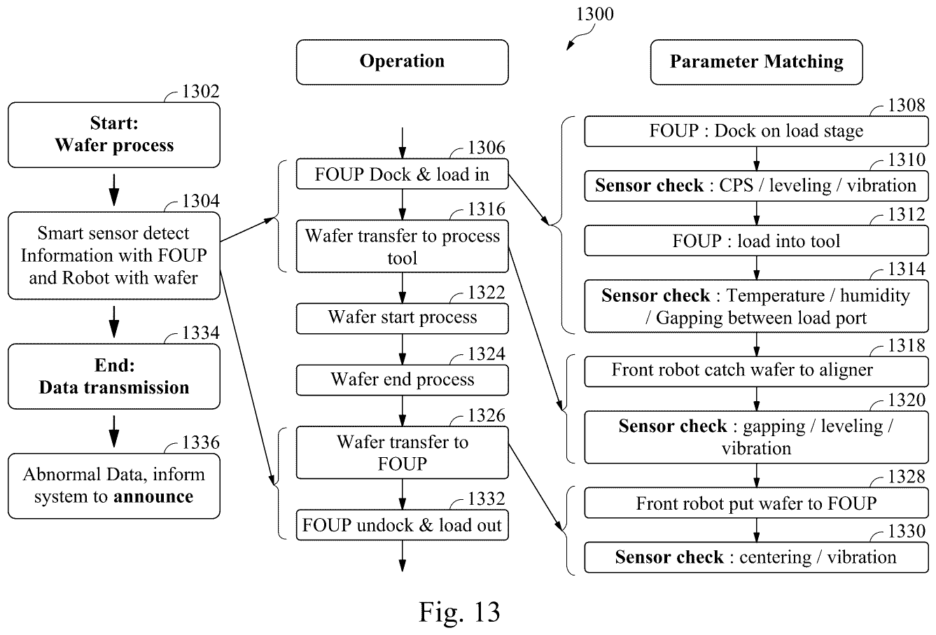

FIG. 13 is a flow diagram of a method 1300, in accordance with some embodiments. The method 1300 can utilize processes, systems, and components described in relation to FIGS. 1-12. At 1302, a wafer process begins. The beginning of the wafer process includes transporting a transport case that holds the wafer to a load/unload system of a process tool. At 1304, sensor data is generated with regard to loading the transport case at the load/unload system, retrieving a wafer from the transport case with a robot arm, and loading the wafer back into the transport case with the robot arm after a semiconductor process has been performed on the wafer with a process tool. 1304 includes steps 1306-1332.

At 1306, the transport case (i.e., a FOUP) is not docked and loaded at a load/unload system of a process tool. 1306 includes the steps 1308-1314. At 1308, the FOUP is docked at the loading stage of the load/unload system. At 1310, one or more sensors of the FOUP generate sensor data related to alignment or positioning of the contamination prevention system pins (door pins and bottom pins) relative to slots of the FOUP. One or more sensors of the FOUP generate sensor data related to the leveling of the FOUP on the loading stage. One or more sensors of the FOUP generate sensor data related to vibrations of the FOUP on the loading stage. At 1312, the FOUP is loaded onto the load/unload system. At 1314, one or more sensors of the FOUP generate sensor data indicating the temperature, humidity, and pressure within the FOUP. One or more sensors of the FOUP also generate sensor data related to the angle of the front door and the door removal tool.

1316, a robot arm transfers a wafer from the FOUP to the process tool. 1316 includes 1318 and 1320. At 1318, a front robot extends a robot arm into the FOUP to retrieve a wafer. At 1320, one or more sensors of the FOUP generate sensor data indicating the gap between wafers within the FOUP. One or more sensors generate sensor data indicating leveling of the wafer on the robot arm. One or more sensors of the FOUP generate sensor data indicating vibrations as the wafer is retrieved by the robot arm.

At 1322, the wafer is loaded into the process tool and the process tool performs a semiconductor process on the wafer. At 1324, the semiconductor process ends.

At 1326, the wafer is transferred from the process tool to the FOUP. 1326 includes 1328 and 1330. At 1328, the robot arm loads the wafer into a FOUP. At 1330, one or more sensors of the FOUP generate sensor data related to centering of the wafer being loaded into a slot of the FOUP by the robot arm. One or more sensors of the FOUP generates sensor data indicating vibrations of the wafer as the robot arm loads the wafer into the FOUP.

At 1334, all of the sensor data generated in the previous steps is transmitted to a control system. At 1336, the control system analyzes the sensor data to determine whether or not the sensor data represents abnormalities or faults. If abnormalities are false are detected, the control system can announce such abnormalities or faults. The control system can also stop one or more processes or adjust one or more processes responsive to the sensor data.

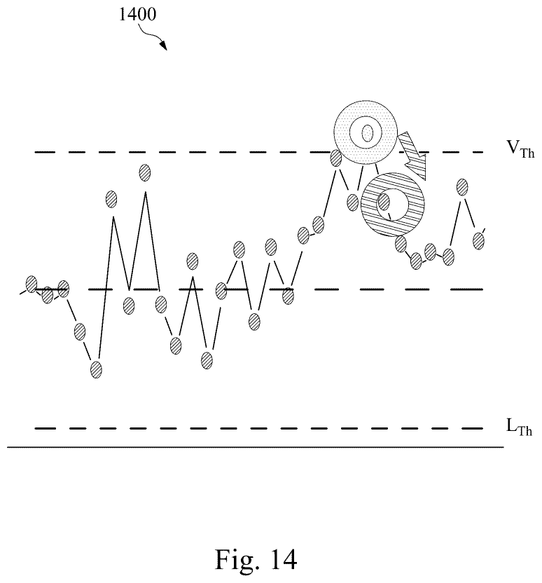

FIG. 14 is a graph 1400 indicating sensor data. The sensor data can correspond to sensor data generated as described in relation to FIGS. 1-13 in relation to loading a transfer case onto a load/unload system of a process tool and loading and unloading it wafers from the transfer case with a robot arm. The graph 1400 includes an upper threshold UTh and a lower threshold LTh. In some embodiments, if the sensor data rises above the upper threshold Uth or passes below the lower threshold LTh, then the control system can stop a current process such as a loading of a transfer case onto a load/unload system or loading or unloading a wafer from the transport case with a robot arm. In some embodiments, the control system can adjust a current process in response to the sensor data going above the upper threshold UTh or going below the lower threshold LTh.

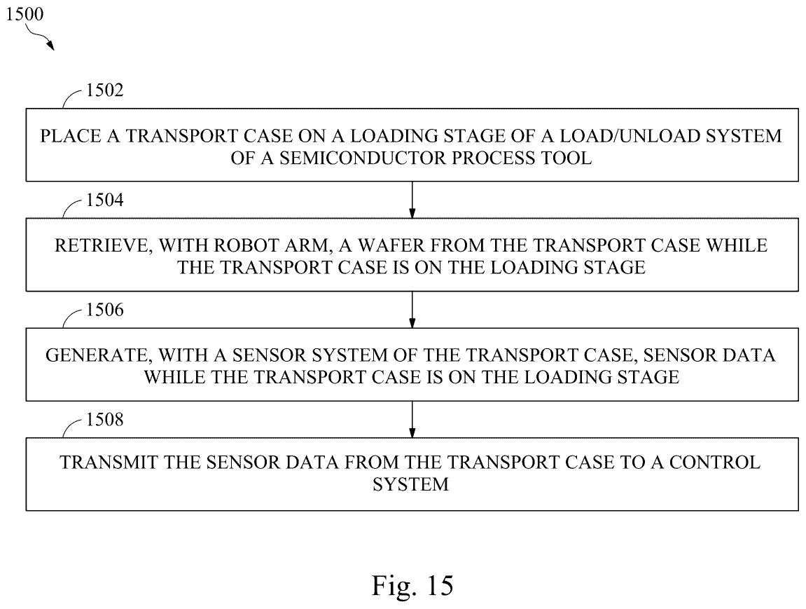

FIG. 15 is a flow diagram of a method 1500, in accordance with some embodiments. The method 1500 can utilize processes, systems, and components described in relation to FIGS. 1-14. At 1502, the method 1500 includes placing a transport case on a loading stage of a load/unload system of a semiconductor process tool. One example of a transport case is the transport case 102 of FIG. 1. One example of a load/unload system is the load/unload system 106 of FIG. 1. One example of a load/unload stage is the load/unload stage 129 of FIG. 3A. One example of a semiconductor process tool is the process tool 107 of FIG. 1. At 1504, the method 1500 includes retrieving, with a robot arm, a wafer from the transport case while the transport case is on the loading stage. One example of a robot arm is the robot arm 139 of FIG. 3A. One example of a wafer is the wafer 110 of FIG. 2. At 1506, the method 1500 includes generating, with a sensor system of the transport case, sensor data while the transport case is on the loading stage. One example of a sensor system is the sensor system 112 of FIG. 1. At 1508, the method 1500 includes transmitting the sensor data from the transport case to a control system. One example of a control system is the control system 104 of FIG. 1.

Embodiments of the present disclosure help ensure that semiconductor wafers or other sensitive semiconductor processing equipment or materials are not damaged during transport, loading, and unloading. Embodiments of the present disclosure provide a wafer transport case, often termed a front opening unified pod (FOUP), with a sensor system including a plurality of sensors mounted within the transport case. The transport case includes a plurality of slots each configured to receive and hold a wafer. The sensor system generates sensor data while the transport case is loaded at a load/unload system of a semiconductor process tool. The sensor system generates sensor data indicative of conditions at the transport case upon arrival at the load/unload system and while a robot arm unloads and loads the wafers from the transport case. The transport case also includes a communication system that can transmit sensor data or other alerts to an external control system so that the external control system can take action to prevent damage to wafers based on the sensor data.

The wafer transport case in accordance with embodiments of the present disclosure provides several benefits. The sensor system can detect that wafers or the transport case itself are in a position that could result in damage to the wafers if not addressed. The sensor system can detect misalignment or other risk factors that are present during loading and unloading of wafers. The wafer transport case can transmit sensor data to the external control system so that the external control system can take steps to correct alignment or positioning issues prior to transporting the transport case, unloading wafers, or loading wafers. This ensures that semiconductor wafers and other sensitive equipment are not damaged during transport, loading, or unloading. The result is better functioning integrated circuits and improved wafer yields.

In some embodiments, a method includes placing a transport case on a loading stage of a load/unload system of a semiconductor process tool and retrieving, with a robot arm, a wafer from the transport case while the transport case is on the loading stage. The method includes generating, with a sensor system of the transport case, sensor data while the transport case is on the loading stage and transmitting the sensor data from the transport case to a control system.

In some embodiments, a transport case includes a slot configured to receive and hold a wafer and a sensor system. The sensor system includes a first sensor configured to generate first sensor data and a second sensor configured to generate second sensor. The transport case includes a communication system configured to transmit the first and second sensor data to a control system remote from the transport case.

In some embodiments, a system includes a transport case. The transport case includes a slot configured to hold a wafer, a sensor system configured to generate sensor data, and a communication system configured to transmit the sensor data. The system includes a semiconductor process tool including a load/unload system configured to receive the transport case and to unload the wafer from the transport case with a robot arm. The system includes a control system configured to receive the sensor data and to control the load/unload system responsive to the sensor data.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
placing a transport case on a loading stage of a load/unload system of a semiconductor process tool;
retrieving, with a robot arm, a wafer from the transport case while the transport case is on the loading stage;
generating, with a sensor system of the transport case, sensor data while the transport case is on the loading stage; and
transmitting the sensor data from the transport case to a control system.

2. The method of claim 1, comprising analyzing the sensor data with an analysis model of the control system.

3. The method of claim 2, comprising stopping the load/unload system with the control system if the analysis model detects a fault condition based on the sensor data.

4. The method of claim 2, comprising adjusting a process of the load/unload system if the analysis model detects a fault condition based on the sensor data.

5. The method of claim 2, wherein the analysis model is trained with a machine learning process.

6. The method of claim 1, wherein generating sensor data includes generating sensor data indicating alignment of contamination prevention system pins of the load/unload system.

7. The method of claim 6, wherein the pins are door pins of door removal tool of the load/unload system configured to remove a door of the transport case.

8. The method of claim 6, wherein the pin are bottom pins of the loading stage configured to secure the transport case on the loading stage.

9. The method of claim 1, wherein generating sensor data includes generating sensor data indicating vibration of the loading stage.

10. The method of claim 1, wherein generating sensor data includes generating sensor data indicating whether or not transport case is level on the unloading stage.

11. The method of claim 1, wherein generating sensor data includes generating sensor data indicating one or more of pressure, temperature, or humidity within the transport case while the transport case is on the loading stage.

12. The method of claim 1, wherein generating sensor data includes generating sensor data indicating vibrations while the robot arm retrieves the wafer from the transport case.

13. The method of claim 1, wherein generating sensor data includes generating sensor data indicating vibrations while the robot arm retrieves the wafer from the transport case.

14. The method of claim 1, comprising loading the wafer into the transport case with the robot arm, wherein generating sensor data includes generating sensor data indicating whether the wafer is centered with respect to a slot of the transport case while the robot arm loads the wafer into the transport case.

15. A transport case, comprising:
a slot configured to receive and hold a wafer;
a sensor system including:
a first sensor configured to generate first sensor data; and
a second sensor configured to generate second sensor data; and
a communication system configured to transmit the first and second sensor data to a control system remote from the transport case.

16. The transport case of claim 15, wherein the first sensor data indicates vibrations within the transport case and the second sensor data indicates an orientation of the wafer within the transport case.

17. The transport case of claim 16, wherein the first sensor data indicates a temperature within the transport case and the second sensor data indicates a humidity within the transport case.

18. A system, comprising:
a transport case including:
a slot configured to hold a wafer;
a sensor system configured to generate sensor data; and
a communication system configured to transmit the sensor data;
a semiconductor process tool including a load/unload system configured to receive the transport case and to unload the wafer from the transport case with a robot arm; and
a control system configured to receive the sensor data and to control the load/unload system responsive to the sensor data.

19. The system of claim 18, wherein the control system is configured to control the load/unload system to adjust a temperature or humidity within the transport case response to the sensor data.

20. The system of claim 18, further comprising an overhead track transport system configured to carry the transport case.
